(19) United States
(12) Patent Application Publication
(10) Pub. No.: US 2026/0090209 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-Si (KR)

(72) Inventors: Joo Hee JEON, Yongin-si (KR); Gun Hee KIM, Yongin-si (KR); Sang Hee JANG, Yongin-si (KR); Sun Young JUNG, Yongin-si (KR)

(21) Appl. No.: 19/210,227

(22) Filed: May 16, 2025

(30) Foreign Application Priority Data
Sep. 23, 2024 (KR) 10-2024-0128310

(51) Int. Cl. H10K 59/122; H10K 59/131; H10K 59/40

(52) U.S. Cl. CPC H10K 59/122; H10K 59/131; H10K 59/40

(57) ABSTRACT

A display device is disclosed that includes a display panel including a plurality of pixels configured to display an image. The display panel is divided into a plurality of areas including a first area and a second area. A pixel disposed adjacent to a boundary between the first area and a second area includes a separation layer.

### CROSS-REFERENCE TO RELATED APPLICATION

The present application claims priority under 35 U.S.C. § 119(a) to Korean patent application No. 10-2024-0128310 filed on Sep. 23, 2024 in the Korean Intellectual Property Office, the entire disclosure of which is incorporated herein by reference.

### BACKGROUND

### 1. Technical Field

The present disclosure generally relates to a display device and electronic device including the same.

### 2. Related Art

A display device display images on a screen, and examples include Liquid Crystal Display (LCD), an Organic Light Emitting Diode (OLED) display, and the like. Display devices are used in various electronic devices, such as mobile phones, navigation systems, digital cameras, electronic books, portable game consoles, and various terminals.

An OLED display includes two electrodes and an organic light emitting layer located therebetween, and electrons injected from one electrode and holes injected from the other electrode combine in the organic light emitting layer, thereby forming excitons. As the excitons generate energy while being changed from an excited state to a ground state, light is emitted.

The above information disclosed in this Related Art section is only for enhancement of understanding of the background of the disclosure and therefore it may contain information that does not form the prior art that is already known in this country to a person of ordinary skill in the art.

### SUMMARY

Embodiments provide a display device in which a driving voltage is separately supplied to areas of a display panel, so that power consumption can be reduced and an image artifact at a boundary between the areas can be avoided.

An embodiment of a display device includes: a display panel including a plurality of pixels which are configured to display an image. The display panel may be divided into a plurality of areas including a first area and a second area. A pixel disposed adjacent to a boundary between the first area and the second area includes a separation layer.

The separation layer may extend parallel to the boundary, and be continuous.

The separation layer may have a trapezoidal shape in a cross-sectional view.

The separation layer may have an inverted trapezoidal shape in a cross-sectional view.

A first-first electrode included in a first pixel adjacent to the boundary in the first area and may be electrically separated by the separation layer from a second-first electrode included in a second pixel adjacent to the boundary in the second area.

The first-first electrode and the second-first electrode may be formed in a same layer. Voltages applied to the first-first electrode and the second-first electrode may be different from each other.

The separation layer may be formed on a pixel defining layer.

The separation layer may include one or more continuous sections parallel to the boundary and one or more discontinuous sections.

The continuous sections and the discontinuous sections may be alternately disposed.

The separation layer may have a trapezoidal shape in a cross-sectional view.

The separation layer may have an inverted trapezoidal shape in a cross-sectional view.

In the continuous section, a first-first electrode included in a first pixel adjacent to the boundary and is included in the first area may be electrically separated by the separation layer from a second-first electrode included a second pixel adjacent to the boundary in the second area. In the discontinuous section, a third-first electrode included in a third pixel adjacent to the boundary in the first area is electrically connected to a fourth-first electrode included in a second pixel adjacent to the boundary in the second area.

The first-first electrode and the second-first electrode may be formed in a same layer. Voltages applied to the first-first electrode and the second-first electrode may be different from each other.

The separation layer may be formed on a pixel defining layer.

An embodiment of an electronic device includes: a display panel including a plurality of pixels which are configured to display an image, and an encapsulation layer disposed on the display panel. The display panel is divided into a plurality of areas including a first area and a second area. A pixel disposed adjacent to a boundary between the first area and the second area includes a separation layer.

The electronic device may further include a touch sensor disposed on the display panel, and a window disposed on the touch sensor.

The electronic device may further include a data driver electrically connected to the display panel, a scan driver electrically connected to the display panel, and an emission driver electrically connected to the display panel.

The electronic device may be a tablet PC, a television, a smartphone, a notebook computer, a head mounted display, a display included in an automobile dashboard, a navigation system display, a digital camera, an electronic book, or a portable game console.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a view illustrating a display device in accordance with embodiments of the present disclosure.

FIG. 2 is a cross-sectional view taken along line I-I′ shown in FIG. 1.

FIG. 3 is a diagram illustrating a display device in accordance with embodiments of the present disclosure.

FIG. 4 is a diagram illustrating a pixel in accordance with embodiments of the present disclosure.

FIG. 5 is a plan view of the display device shown in FIG. 1 in accordance with embodiments of the present disclosure.

FIG. 6 is a schematic cross-sectional view taken along line II-II′ shown in FIG. 5 in accordance with an embodiment of the present disclosure.

FIG. 7 is a schematic cross-sectional view taken along the line II-II′ shown in FIG. 5 in accordance with another embodiment of the present disclosure.

FIG. 8 is a schematic cross-sectional view taken along line III-III′ shown in FIG. 5 in accordance with an embodiment of the present disclosure.

FIG. 9 is a schematic cross-sectional view taken along the line III-III′ shown in FIG. 5 in accordance with another embodiment of the present disclosure.

FIG. 10 is a block diagram of an electronic device according to an embodiment.

FIG. 11 shows schematic views of various embodiments of an electronic device.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ). As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

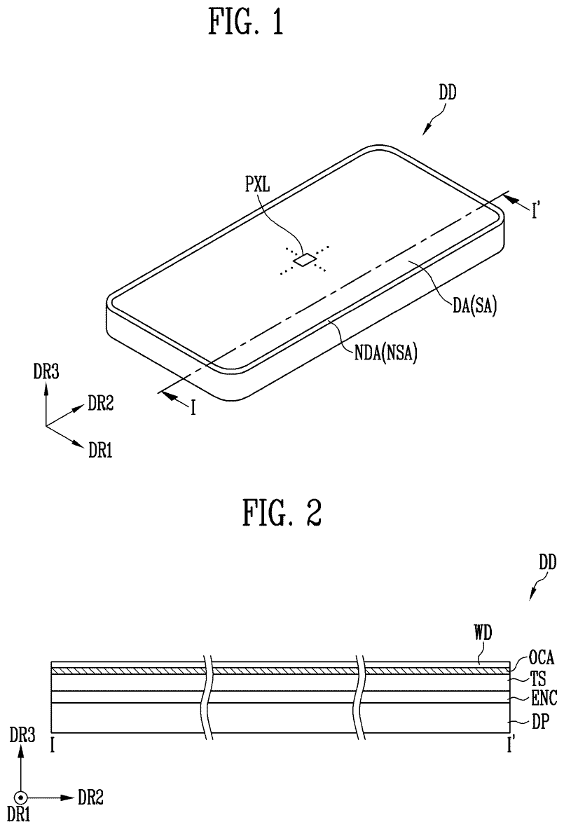

FIG. 1 is a view illustrating a display device in accordance with embodiments of the present disclosure.

Referring to FIG. 1, the display device DD means a device capable of providing visual data to a user. The display device defined in this specification means a device including a light emitting element capable of emitting light when an electrical signal is applied thereto. That is, the display device DD in accordance with the embodiments of the present disclosure is not limited to a specific application target (or electronic device) such as a tablet PC, a television, a smartphone, a notebook computer, a head mounted display, a display included in an automobile dashboard, a navigation system display, a digital camera, an electronic book, or a portable game console.

The display device DD may include a display area DA, a non-display area NDA, a sensing area SA, and a non-sensing area NSA.

The display device DD may not only display an image through the sensing area SA, but also sense a touch input applied from the user or sense light incident at the front. A touch sensor of the display device DD may be located in the sensing area SA.

The touch sensor of the display device DD may not be located in the non-sensing area NSA. The non-sensing area NSA may surround the sensing area SA. However, this is merely illustrative, and the present disclosure is not limited thereto.

In accordance with an embodiment, a partial area of the display area DA may correspond to the sensing area SA. A partial area of the non-display area NDA may correspond to the non-sensing area NSA.

The display area DD may output visual information at the front of the display device DD. The display device DD may include at least one pixel PXL. The pixels PXL may be located in the display area DA.

Each of the pixels PXL may include a light emitting element. The light emitting element defined in this specification may include a material severing as a light source emitting light when an electrical signal is applied thereto. Each of the pixels PXL may emit light in the display area DA when an electrical signal corresponding to image data to be output is applied thereto.

The light emitting element may be an inorganic light emitting element including an inorganic light emitting material or a light emitting element (or a quantum dot display element) emitting light by changing a wavelength of the emitted light, using a quantum dot. In some embodiments, the light emitting element may be an organic light emitting element including an organic light emitting material.

FIG. 2 is a cross-sectional view taken along line I-I′ shown in FIG. 1.

Referring to FIG. 2, the display device DD may include a display panel DP, an encapsulation layer ENC, a touch sensor TS, an optically clear adhesive member OCA, and a window WD.

The display panel DP may output visual data. At least one of self-luminescent display panels, such as an Organic Light Emitting Display panel (OLED panel) using an organic light emitting diode as a light emitting element, a nano-scale LED display panel using a nano-scale LED as a light emitting element, and a Quantum Dot Organic Light Emitting Display panel (QD OLED panel) using a quantum dot and an organic light emitting diode may be used as the display panel. However, the present disclosure is not limited to the above-described example, and the display panel DP may be at least one of a Liquid Crystal Display panel (LCD panel), an Electro-Phoretic Display panel (EPD panel), and an Electro-Wetting Display panel (EWD panel).

Hereinafter, for convenience, a case where the light emitting element included in the display device DD is an organic light emitting diode will be mainly described.

The encapsulation layer ENC may be disposed on the display panel DP. The encapsulation layer ENC may prevent infiltration of external moisture and oxygen into the display panel DP.

The touch sensor TS may be located on the encapsulation layer ENC. The touch sensor TS may be located in the sensing area (see ‘SA’ shown in FIG. 1). The display panel DP and the touch sensor TS may be integrally manufactured. The touch sensor TS may be formed directly on at least one layer constituting the display panel DP, e.g., the encapsulation layer ENC located on the top of the display panel DP.

When a touch input is applied from the user, the touch sensor TS may acquire information on the touch input. The touch sensor TS may recognize a touch input, using a capacitive sensing type. The touch sensor TS may sense a touch input, using a mutual capacitance type or sense a touch input, using a self-capacitance type.

The window WD may be located on the touch sensor TS. The window WD may be a transparent transmissive substrate. The window WD and the touch sensor TS may be bonded to each other through the optically clear adhesive member OCA. The window WD may reduce external impact against the display device DD while allowing visual information to be transmitted therethrough. In an example, the window WD may be implemented using rigid glass, flexible plastic, or the like. However, embodiments of the present disclosure are not limited thereto.

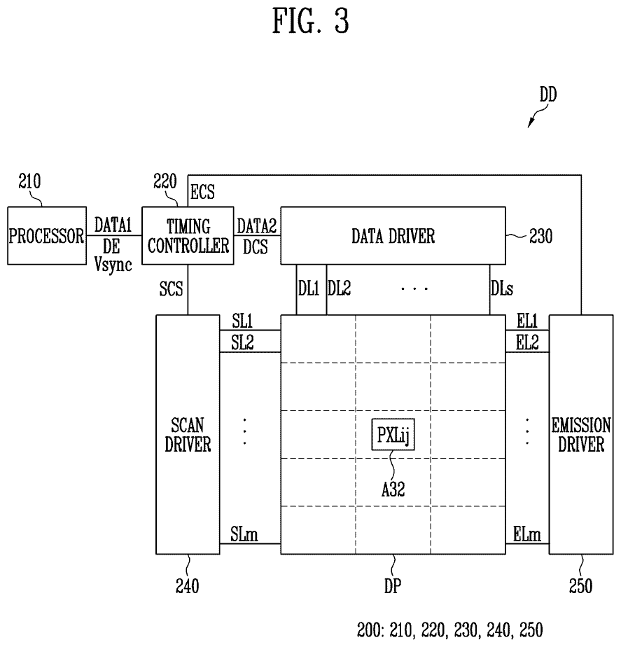

FIG. 3 is a diagram illustrating a display device in accordance with embodiments of the present disclosure.

Referring to FIG. 3, the display device DD in accordance with the embodiments of the present disclosure may include a display panel DP and a display driver 200. The display driver 200 may include a processor 210, a timing controller 220, a data driver 230, a scan driver 240, and an emission driver 250.

The display panel DP may display an image, corresponding to a variable driving frequency. The driving frequency is a frequency at which data voltages (or data signals DATA) are substantially written to a driving transistor of a pixel for one second. For example, the driving frequency is also referred to as a screen scan rate or a screen refresh frequency, and represents a frequency at which an image is refreshed for one second.

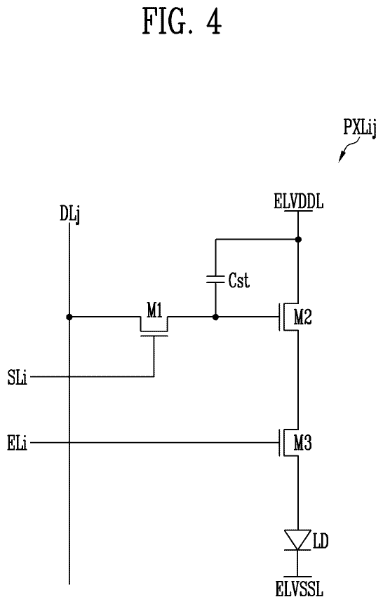

The display panel DP may include pixels PXL. Each of the pixels PXL may be connected to a corresponding data line and a corresponding scan line. For example, any one pixel PXLij among the pixels PXL may mean a pixel in which a scan transistor is connected to an ith scan line and a jth data line (i and j are integers greater than 0). The pixel PXLij will be described in detail later with reference to FIG. 4.

The display panel DP may be divided into a plurality of areas. In FIG. 3, the display panel DP is divided into a total of fifteen areas as five rows and three columns. However, embodiments are not necessarily limited thereto. The display panel DP may be divided into various numbers of areas.

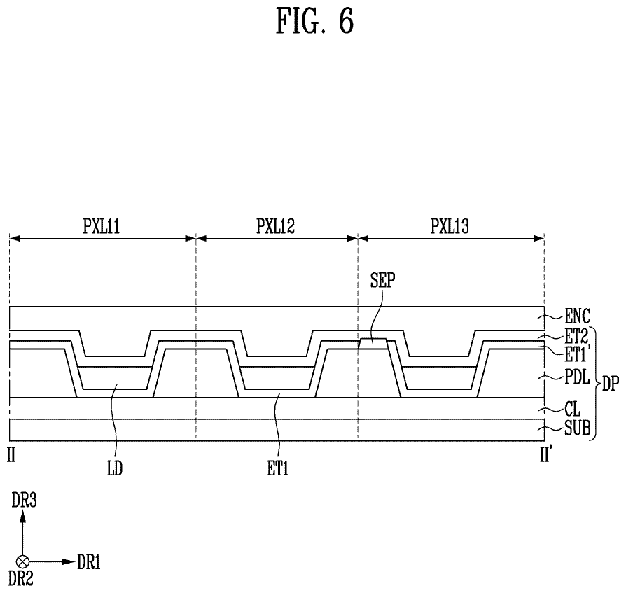

The display panel DP may be divided into a plurality of areas by a separation layer SEP or SEP′ (see FIGS. 6 to 8). A second power voltage may be individually applied to adjacent areas separated by the separation layer SEP or SEP′. This will be described later with reference to FIGS. 6 to 8.

In FIG. 3, it is illustrated that the pixel PXLij is located in an area A32 located in a third row and a second column.

The second power voltage may be separately applied for each area of the display panel DP. Accordingly, a magnitude of the second power voltage applied for each area of the display panel DP may be individually determined. For example, the second power voltage having different magnitudes may be applied for each area of the display panel DP. For example, a magnitude of the second power voltage applied to the pixel PXLij located in the area A32 located on the third row and the second column may be different from a magnitude of the second power voltage applied to pixels PXL located in peripheral areas.

When magnitudes of the second power voltage applied to all areas of the display panel DP are the same, the second power voltage having an unintendedly large magnitude is applied even though a magnitude of the second power voltage applied to any area of the display panel DP can be small, and therefore, power consumption may be unnecessarily increased.

In the display device DD in accordance with the embodiments of the present disclosure, the second power voltage may be separately applied for each area of the display panel DP, and a magnitude of the second power voltage applied for each area of the display panel DP may be individually determined. Accordingly, power consumption in driving of the display device DD can be decreased.

The processor 210 may be configured as a Graphics Processing Unit (GPU), a Central Processing Unit (CPU), an Application Processor (AP), or the like. The processor 210 may refer to a single integrated chip (IC) or refer to a group configured with a plurality of ICs.

The processor 210 may supply a timing control signal and first image data DATA1 to the timing controller 220.

The timing control signal may include a data enable signal DE, a vertical synchronization signal Vsync, and the like. The vertical synchronization signal Vsync may define frame periods. The vertical synchronization signal Vsync may include a high level period and a low level period.

Each frame period (FR) may be started at a time point at which the vertical synchronization signal Vsync is changed from a high level to a low level.

The data enable signal DE may define a blank period and a display period, which are included in each of frame periods. For example, the data enable signal DE may have a high level in display periods, and have a low level in a blank period.

During a period in which the data enable signal DE maintains the high level, data signals may be output from the data driver 230.

An image may be displayed on the display panel DP in a unit of a frame period. More specifically, data signals corresponding to an image may be supplied to the display panel DP in a display period of a frame period, thereby displaying the image. In addition, the display panel DP may not display the image in a blank period of the frame period.

The timing controller 220 may be supplied with the vertical synchronization signal Vsync, the data enable signal DE, the first image data DATA1, and the like from the processor 210. The timing controller 220 may supply control signals respectively to the data driver 230, the scan driver 240, and the emission driver 250, based on signals supplied from the processor 210. For example, the timing controller 220 may supply a data control signal DCS to the data driver 230. The timing controller 220 may supply a scan control signal SCS to the scan driver 240. The timing controller 220 may supply an emission control signal ECS to the emission driver 250.

Also, the timing controller 220 may convert the first data DATA1 input from the processor 210 into second image data DATA2 suitable for specifications of the data driver 230, and supply the second image data DATA2 to the data driver 230.

The data driver 230 may generate data signals DL1 to DLs to be supplied to the display panel DP, using the second image data DATA2 and the data control signal DCS.

The scan driver 240 may receive the scan control signal SCS and the like from the timing controller 220, thereby generating scan signals to be provided to scan lines SL1 to SLm (m is an integer greater than or equal to 1).

The scan driver 240 may sequentially supply scan signals having a pulse of a turn-on level to the scan lines SL1 to SLm. The scan driver 240 may include scan stages configured in the form of shift registers. The scan driver 240 may generate the scan signals in a manner that sequentially transfers a scan start signal in the form of a pulse of a turn-on level to a next scan stage.

The emission driver 250 may receive the emission control signal ECS and the like from the timing controller 220, thereby generating emission signals to be supplied to emission lines EL1 to Elm (m is an integer greater than 0). For example, the emission driver 250 may include emission stages connected to emission lines EL1 to Elm. The emission stages may be configured in the form of shift registers. For example, a first emission stage may generate an emission signal of a turn-off level, based on an emission stop signal of a turn-on level, and the other emission stages may sequentially generate emission signals of a turn-off level, based on an emission signal of a turn-off level in a previous emission stage.

FIG. 4 is a diagram illustrating a pixel in accordance with embodiments of the present disclosure.

Referring to FIG. 4, the pixel PXLij may include transistors M1, M2, and M3, a storage capacitor Cst, and a light emitting diode LD.

Hereinafter, a circuit implemented with an N-type transistor is described as an example. However, those skilled in the art may design a circuit implemented with a P-type transistor by changing the polarity of a voltage applied to a gate electrode. Similarly, those skilled in the art may design a circuit implemented with a combination of the P-type transistor and the N-type transistor. The P-type transistor is commonly called a transistor in which an amount of current flowing therethrough increases when a difference in voltage between a gate terminal and a source terminal increases in a negative direction. The N-type transistor is commonly called a transistor in which an amount of current flowing therethrough increases when a difference in voltage between a gate terminal and a source terminal increases in a positive direction. The transistor may be configured in various forms including a Thin Film Transistor (TFT), a Field Effect Transistor (FET), a Bipolar Junction Transistor (BJT), and the like.

A gate electrode of a first transistor M1 may be connected to an ith scan line SLi, a first electrode of the first transistor M1 may be connected to a jth data line DLj, and a second electrode of the first transistor M1 may be connected to a gate electrode of a second transistor M2. The first transistor M1 may be referred to as a scan transistor.

The gate electrode of the second transistor M2 may be connected to a first electrode of the storage capacitor Cst, a first electrode of the second transistor M2 may be connected to a first power line ELVDDL, and a second electrode of the second transistor M2 may be connected to a first electrode of a third transistor M3. The second transistor M2 may be referred to as a driving transistor.

A gate electrode of the third transistor M3 may be connected to an ith emission line ELi, the first electrode of the third transistor M3 may be connected to the second electrode of the second transistor M2, and a second electrode of the third transistor M3 may be connected to an anode of the light emitting diode LD.

The first electrode of the storage capacitor Cst may be connected to the gate electrode of the second transistor M2, and a second electrode of the storage capacitor Cst may be connected to the first electrode of the second transistor M2.

The anode of the light emitting diode LD may be connected to the second electrode of the third transistor M3, and a cathode of the light emitting diode LD may be connected to a second power line ELVSSL. The light emitting diode LD may be configured as an organic light emitting diode, an inorganic light emitting diode, a quantum dot/well light emitting diode, or the like. Meanwhile, it is exemplarily illustrated that the pixel PXLij shown in FIG. 3 includes one light emitting diode LD. However, in another embodiment, the pixel PXLij may include a plurality of light emitting diodes connected in series, parallel, or series/parallel.

A first power voltage may be applied to the first power line ELVDDL, and a second power voltage may be applied to the second power line ELVSSL. For example, during a display period, the first power voltage may be higher than the second power voltage.

The second power line ELVSSL connected to pixels PXL for each area of the display panel DP may be separated. Accordingly, the second power voltage applied to the pixels PX for each area of the display panel DP may be separated. A magnitude of the second power voltage applied for each area of the display panel DP may be individually determined.

When a scan signal having a turn-on level (here, a logic high level) is applied through the scan line SLi, the first transistor M1 may be in a turn-on state. A data voltage applied to the data line DLj may be stored at the first electrode of the storage capacitor Cst. An emission signal having a turn-off level (here, a logic low level) may be applied through the emission line ELi, and the third transistor M3 may be in a turn-off state.

After that, an emission signal having a turn-on level (here, a logic high level) may be applied through the emission line ELi, and the third transistor M3 may be in a turn-on state. Accordingly, a positive driving current corresponding to a difference in voltage between the first electrode and the second electrode of the storage capacitor Cst may flow between the first electrode and the second electrode of the second transistor M2. As a result, the light emitting diode LD may emit light with a luminance corresponding to data voltages (or data signals DATA).

Next, when a scan signal having a turn-off level (here, a logic low level) is applied through the scan line SLi, the first transistor M1 may be turned off, and the data line DLj and the first electrode of the storage capacitor Cst may be electrically separated from each other. Thus, although data voltages (or data signals) of the data line DLj are changed, the voltage stored at the first electrode of the storage capacitor Cst is not changed.

Embodiments are not limited to the pixel PXLij shown in FIG. 4, and may be applied to pixels of other pixel circuits.

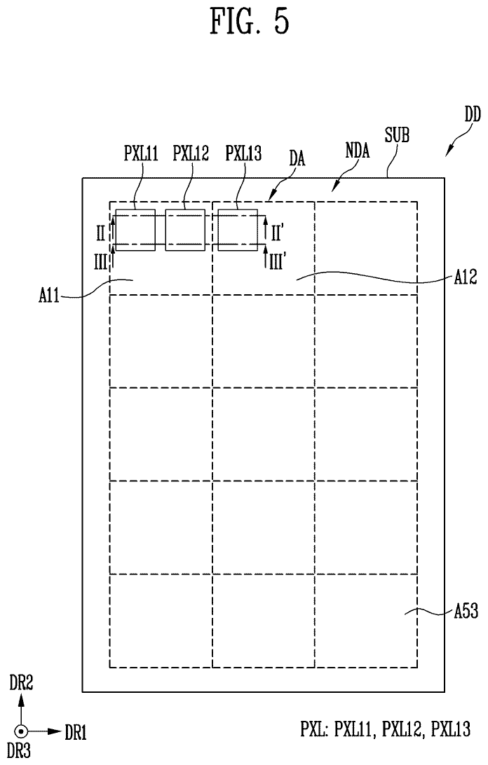

FIG. 5 is a plan view of the display device shown in FIG. 1 in accordance with embodiments of the present disclosure.

Referring to FIG. 5, the display device DD including a base layer SUB may include a display area DA for displaying an image and a non-display area NDA except the display area DA. The display area DA may constitute a screen on which an image is displayed, and the non-display area NDA may be the other area except the display area DA.

For convenience of description, in FIG. 5, a structure of the display device DD will be briefly illustrated based on the display area DA. However, although not shown in FIG. 5, at least one driving circuit (e.g., at least one of a scan driver and a data driver), lines, or pads may be further disposed in the display device DD.

Pixels PXL (see FIG. 1) may be disposed in the display area DA. The pixels PXL may include a pixel PXL11 connected to a first scan line and a first data line, a pixel PXL12 connected to the first scan line and a second data line, and a pixel PXL13 connected to the first scan line and a third data line. In FIG. 5, for convenience of description, only the pixel PXL11 connected to the first scan line and the first data line, the pixel PXL12 connected to the first scan line and the second data line, and the pixel PXL13 connected to the first scan line and the third data line among the pixels PXL are illustrated.

The pixels PXL may be regularly arranged according to a stripe arrangement structure, a PENTILE™ arrangement structure, or the like. For example, the pixel PXL11 connected to the first scan line and the first data line, the pixel PXL12 connected to the first scan line and the second data line, and the pixel PXL13 connected to the first scan line and the third data line may be regularly arranged according to the stripe arrangement structure, the PENTILE™ arrangement structure, or the like. However, the arrangement structure of the pixels PXL is not limited thereto, and the pixels PXL may be arranged in the display area DA according to various structures or various methods.

The display panel DP may be divided into a plurality of areas. For example, the display panel DP is divided into five rows and three columns in FIG. 5. However, embodiments are not necessarily limited thereto, and the display panel DP may be divided into various numbers of areas.

The display panel DP may be divided into a plurality of areas by a separation layer SEP or SEP′ (see FIGS. 6 to 8). A structure of the display panel DP including the separation layer SEP or SEP′ will be described in detail later with reference to FIGS. 6 to 8.

Referring to FIG. 5, the pixel PXL11 connected to the first scan line and the first data line and the pixel PXL12 connected to the first scan line and the second data line are located in an area A11 located on the same first row and the same first column. On the other hand, the pixel PXL13 connected to the first scan line and the third data line is located in an area A12 located on the first row and a second column.

A second power voltage may be separately applied for each area of the display panel DP. Accordingly, a magnitude of the second power voltage applied for each area of the display panel DP may be individually determined. For example, a magnitude of the second power voltage applied to the pixels PXL located in the area A11 located on the first row and the first column may be different from a magnitude of the second power voltage applied to pixels PXL located in the area A12 located on the first row and the second column. However, the second power voltage having the same magnitude may be applied to pixels PXL included in the same area. More specifically, magnitudes of the second power voltage applied to the pixel PXL11 connected to the first scan line and the first data line and the pixel PXL12 connected to the first scan line and the second data line may be the same. However, magnitudes of the second power voltage applied to the pixel PXL11 connected to the first scan line and the first data line and the pixel PXL13 connected to the first scan line and the third data line may be different from each other.

When magnitudes of the second power voltage applied to all the areas of the display panel DP are the same, the second power voltage having an unintendedly large magnitude is applied even though a magnitude of the second power voltage applied to any area of the display panel DP can be small, and therefore, power consumption may be unnecessarily increased.

In the display device DD in accordance with the embodiments of the present disclosure, the second power voltage may be separately applied for each area of the display panel DP, and a magnitude of the second power voltage applied for each area of the display panel DP may be individually determined. Accordingly, power consumption in driving of the display device DD can be decreased.

FIG. 6 is a schematic cross-sectional view taken along line II-II′ shown in FIG. 5 in accordance with an embodiment of the present disclosure. For convenience of description, a touch sensor TS, an optically clear adhesive member OCA, and a window WD will be omitted.

Referring to FIG. 6, the display device DD may include a display panel DP and an encapsulation layer ENC. The display panel DP may include a base layer SUB, a circuit layer CL, pixel defining layers PDL, a first electrode ET1 and ET1′, a separation layer SEP, light emitting diodes (or light emitting layers) LD, and a second electrode ET2. The first electrode ET1 and ET1′ may be referred to as a first-first electrode ET1 and a second-first electrode ET1′, respectively.

In an embodiment of the present disclosure, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot and the like. However, this is merely illustrative, and the like of the display panel DP is not limited thereto.

The base layer SUB may be a polymer substrate, a plastic substrate, a glass substrate, a quartz substrate, or the like. The base layer SUB may be a transparent insulating substrate. The base layer SUB may be a rigid one. The base layer SUB may be a flexible one.

The circuit layer CL may be disposed on the base layer SUB. The circuit layer CL may include a plurality of transistors, and each of the transistors may include a control electrode, an input electrode, and an output electrode.

The pixel defining layer PDL may be disposed on the circuit layer CL.

An area in which the light emitting diodes LD are to be disposed may be divided by the pixel defining layers PDL. The pixel defining layers PDL may be formed, including polyacrylate resin or polyimide resin. Alternatively, the pixel defining layers PDL may be formed of an inorganic material. For example, the pixel defining layers PDL may be formed, including silicon nitride, silicon oxide, silicon oxynitride, or the like

The pixel defining layers PDL may have a trapezoidal shape in a cross-sectional view as shown in FIG. 6. However, embodiments are not necessarily limited thereto. For example, the pixel defining layers PDL may have a quadrangular shape in a cross-sectional view.

The first electrode ET1 and ET1′ may be disposed on the pixel defining layers PDL and the circuit layer CL. The electrode ET1 and ET1′ may be an anode electrode. The pixel PXl11 connected to the first scan line and the first data line and the pixel PXL12 connected to the first scan line and the second data line may include a first electrode ET1. On the other hand, the pixel PXL13 connected to the first scan line and the third data line may include a first electrode ET1′. The second power voltage may be applied to the first electrode ET1 and ET1′.

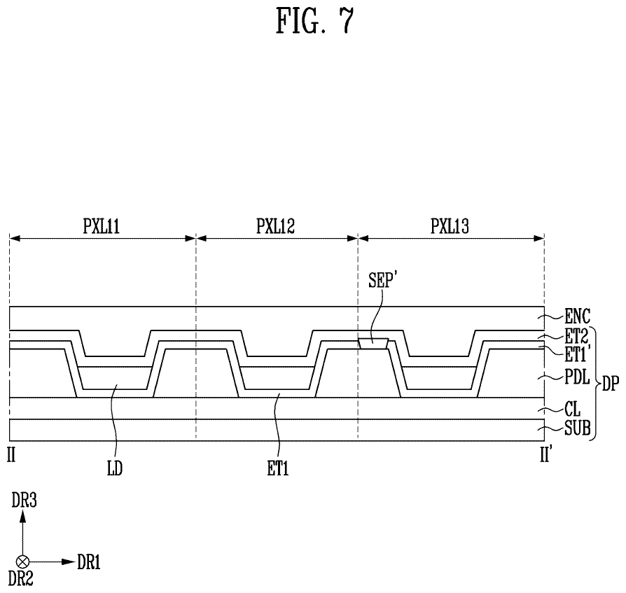

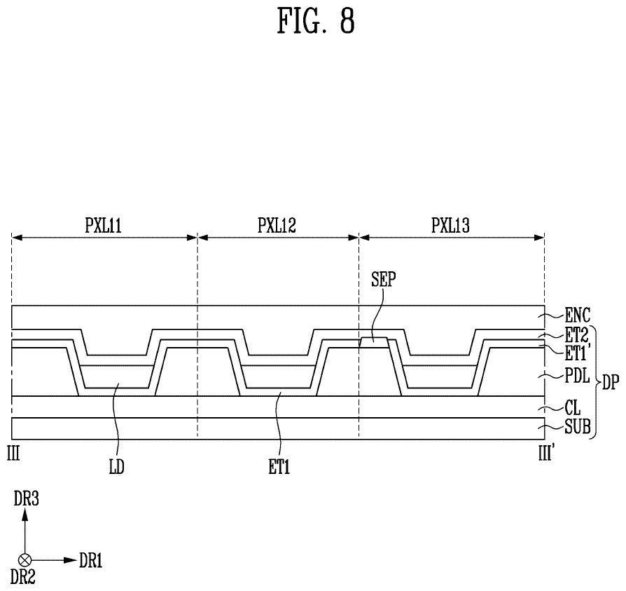

The separation layer SEP may have a trapezoidal shape in a cross-sectional view. Also, the separation layer SEP may be formed on any one pixel defining layer among the pixel defining layers PDL. Note that, while the separation layer SEP as shown in FIG. 6 (as well as the separation layers SEP′ and SEP in FIGS. 7 and 8, respectively) are within the pixel PX13, the separation layer may extend into the pixel PXL12.

The separation layer SEP may extend in a second direction DR2, and the second direction DR2 may be parallel to a direction in which a boundary between the area A11 located on the first row and the first column and the area A12 located on the first row and the second column extends. In other words, the separation layer SEP may extend in a direction in which a boundary between adjacent areas extends.

In an embodiment, the separation layer SEP may extend parallel to a boundary between adjacent area, and be continuous. This will be described with reference to FIGS. 6 and 8.

On the other hand, in another embodiment, the separation layer SEP may extend parallel to a boundary between adjacent area, and include at least one discontinuous section. This will be described with reference to FIGS. 6 to 9.

The separation layer SEP may perform function of dividing areas to which the second power voltage is individually applied in the display panel DP. A detailed description is as follows.

The pixel PXL11 connected to the first scan line and the first data line and the pixel PXL12 connected to the first scan line and the second data line may be included in the same area on the display panel DP. Therefore, the pixel PXL11 connected to the first scan line and the first data line and the pixel PXL12 connected to the first scan line and the second data line may include the same first electrode ET1 without the separation SEP.

The pixel PXL12 connected to the first scan line and the second data line and the pixel PXL13 connected to the first scan line and the third data line may be included in different areas on the display panel DP.

The first electrode ET1 included in the pixel PXL12 connected to the first scan line and the second data line and the first electrode ET1′ included in the pixel PXL13 connected to the first scan line and the third data line may be electrically separated from each other by the separation layer SEP. Accordingly, the second power voltage may be individually applied to the first electrode ET1 included in the pixel PXL12 connected to the first scan line and the second data line and the first electrode ET1′ included in the pixel PXL13 connected to the first scan line and the third data line. For example, the second power voltage having different magnitudes may be applied to the first electrode ET1 included in the pixel PXL12 connected to the first scan line and the second data line and the first electrode ET1′ included in the pixel PXL13 connected to the first scan line and the third data line.

The light emitting diodes LD may be formed on the first electrode ET1 and ET1′. Each of the light emitting diodes LD may include a hole transport region, a light emitting layer, and an electron transport region, which are sequentially stacked.

The second electrode ET2 may be formed on the light emitting diodes LD the first electrode ET1 and ET1′, and the separation layer SEP. The second electrode ET2 may correspond to an electrode to which the first power voltage having a magnitude greater than the magnitude of the second power voltage.

The same second electrode ET2 may be disposed throughout all of the pixel PX11 connected to the first scan line and the first data line, the pixel PXL12 connected to the first scan line and the second data line, and the pixel PX13 connected to the first scan line and the third data line.

The encapsulation layer ENC may be disposed over the second electrode ET2 to seal the display panel DP. The encapsulation layer ENC may protect the display panel from moisture or oxygen, and protect the display panel DP from a foreign matter such as a dust particle. The encapsulation layer ENC may be one including at least one inorganic layer or at least one organic layer. The encapsulation layer ENC may have a structure in which an organic layer and an inorganic layer are alternately and repeatedly stacked. For example, the encapsulation layer ENC may be a structure in which an inorganic layer, an organic layer, and an inorganic layer are sequentially stacked.

FIG. 7 is a schematic cross-sectional view taken along the line II-II′ shown in FIG. 5 in accordance with another embodiment of the present disclosure. For convenience of description, a touch sensor TS, an optical clear adhesive member OCA, and a window WD will be omitted.

Referring to FIG. 7, the display device DD may include a display panel DP and an encapsulation layer ENC. The display panel DP may include a base layer SUB, a circuit layer CL, pixel defining layers PDL, a first electrode ET1 and ET1′, a separation layer SEP′, a light emitting diode (or light emitting layer) LD, and a second electrode ET2.

As compared with the description shown in FIG. 6, FIG. 7 may be different from FIG. 6 in that the separation layer SEP′ has an inverted trapezoidal shape in a cross-sectional view. Hereinafter, overlapping descriptions of the other components will be omitted.

FIG. 8 is a schematic cross-sectional view taken along line III-III′ shown in FIG. 5 in accordance with an embodiment of the present disclosure. For convenience of description, a touch sensor TS, an optical clear adhesive member OCA, and a window WD will be omitted.

Referring to FIG. 8, the display device DD may include a display panel DP and an encapsulation layer ENC. The display panel DP may include a base layer SUB, a circuit layer CL, pixel defining layers PDL, a first electrode ET1 and ET1′, a separation layer SEP, a light emitting diode (or light emitting layer) LD, and a second electrode ET2.

The display device DD in accordance with the embodiment of the present disclosure is described with reference to FIGS. 6 and 8. The display device DD in accordance with the embodiment of the present disclosure may include a separation layer SEP which extends parallel to a boundary between adjacent areas and is continuous.

Referring to FIG. 6, when a section of the display panel DP shown in FIG. 5, which is taken along the line II-II′, is viewed, it can be seen that the display panel DP includes the separation layer SEP.

Also, referring to FIG. 8, when a section of the display panel DP shown in FIG. 5, which is taken along the line III-III′, is viewed, it can be seen that the display panel DP also includes the separation layer SEP.

As such, when sections taken along a line extending in a direction perpendicular to a boundary between adjacent areas are viewed, it can be seen that all the sections include the separation layer SEP. This may result from that the display device DD in accordance with the embodiment of the present disclosure includes the separation layer SEP which extends parallel to a boundary between adjacent areas and is continuous.

In addition, the display device DD in accordance with the embodiment of the present disclosure may individually determine a magnitude of the second power voltage applied to each area of the display panel DP. Accordingly, unnecessary supply of the second power voltage can be minimized, thereby reducing power consumption.

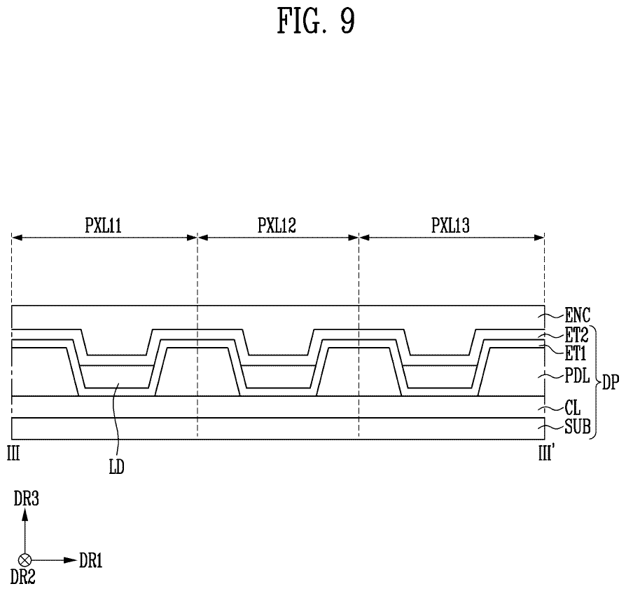

FIG. 9 is a schematic cross-sectional view taken along the line III-III′ shown in FIG. 5 in accordance with another embodiment of the present disclosure. For convenience of description, a touch sensor TS, an optical clear adhesive member OCA, and a window WD will be omitted.

Referring to FIG. 9, the display device DD may include a display panel DP and an encapsulation layer ENC. The display panel DP may include a base layer SUB, a circuit layer CL, pixel defining layers PDL, a first electrode ET1, a separation layer SEP, a light emitting diode (or light emitting layer) LD, and a second electrode ET2.

The display device DD in accordance with the another embodiment of the present disclosure will be described with reference to FIGS. 6 and 9. The display device DD in accordance with the another embodiment of the present disclosure may include a separation layer SEP which extends parallel to a boundary between adjacent areas and includes at least one continuous section and at least one discontinuous section. For example, the display device DD in accordance with the another embodiment of the present disclosure may include a separation layer in which a continuous section and a discontinuous section are alternately disposed.

Referring to FIG. 6, when a section of the display panel DP shown in FIG. 5, which is taken along the line II-II′, is viewed, it can be seen that the display panel DP includes the separation layer SEP. Referring to FIG. 6, a section in which the separation layer SEP is continuous can be seen.

On the other hand, referring to FIG. 9, when a section of the display panel DP shown in FIG. 5, which is taken along the line III-III′, is viewed, it can be seen that the display panel DP does not include the separation layer SEP. Accordingly, it can be seen that pixels PXL included in each of adjacent areas equally include the first electrode ET1. For example, it can be seen that although the pixel PXL12 connected to the first scan line and the second data line and the pixel PXL13 connected to the first scan line and the third data line are pixels PXL included in different areas, the pixel PXL12 and the pixel PXL13 equally include the first electrode ET1. In addition, since the pixel PXL12 and the pixel PXL13 equally include the first electrode ET1, the second power voltage having the same magnitude may be applied. Referring to FIG. 9, a section in which the separation layer SEP is discontinuous can be seen. The first electrode ET1 and ET1′ may be referred to as a first-first electrode ET1 and a second-first electrode ET1′, respectively.

As such, when sections taken along a line extending in a direction perpendicular to a boundary between adjacent areas are viewed, it can be seen that a section in which the separation SEP is continuous and a section in which the separation layer SEP is discontinuous are simultaneously provided.

The display device DD in accordance with the another embodiment of the present disclosure may individually determine a magnitude of the second power voltage applied to each area of the display panel DP. Accordingly, unnecessary supply of the second power voltage can be minimized, thereby reducing power consumption.

Additionally, as compared with the display device DD in accordance with the embodiment of the present disclosure, the display device DD in accordance with the another embodiment of the present disclosure includes a separation layer SEP including at least one discontinuous section.

Since the separation layer SEP is located between adjacent areas, the second power voltage having different magnitudes may be applied to the adjacent area. At the same time, the second power voltage having the same magnitude may be applied to each of adjacent area in a section in which the separation layer SEP is discontinuous between the adjacent areas.

Even when the second power voltage having different magnitudes is applied to adjacent area, there can be obtained an effect that a voltage having an average magnitude of the second power voltage applied to each of the adjacent areas is applied in a boundary between adjacent areas.

Accordingly, there can be obtained an effect that the magnitude of the second power voltage applied toward another area from one area among adjacent areas gradually increases. In addition, a boundary between adjacent areas to which the second power voltage having different magnitudes is applied can be efficiently prevented from being viewed.

In the display device in accordance with the present disclosure, a driving voltage is separately supplied for each area to a display panel, so that power consumption can reduced and it can be minimized that a boundary between areas of the display panel is viewed due to area separation.

A display device according to an embodiment is applicable to various types of electronic devices. In an embodiment, an electronic device includes the above-described display device and may further include other modules or devices having additional functions in addition to the display device.

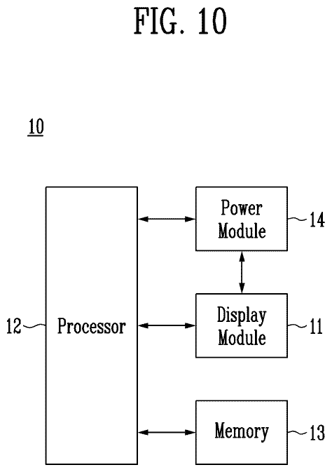

FIG. 10 is a block diagram of an electronic device according to an embodiment. Referring to FIG. 10, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

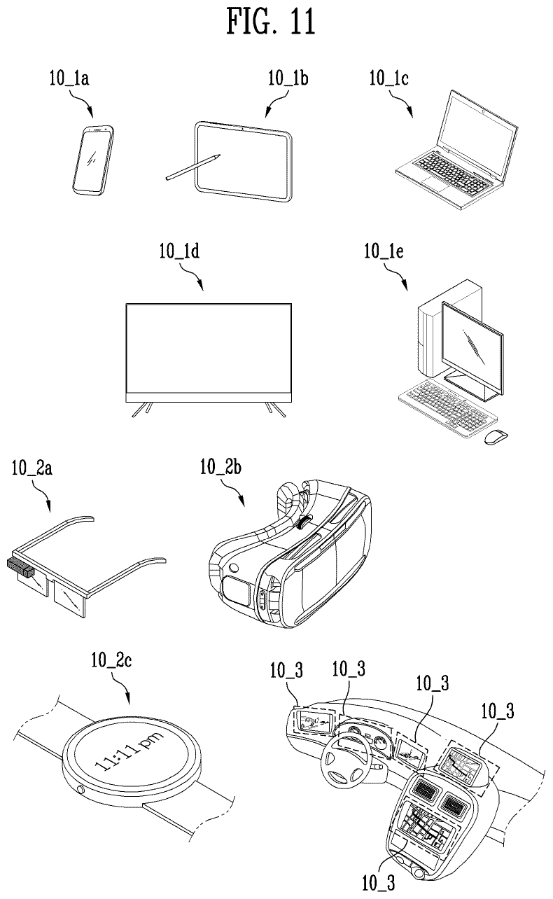

FIG. 11 shows schematic views of various embodiments of an electronic device.

Referring to FIG. 11, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, or elements described in connection with a particular embodiment may be used singly or in combination with features, characteristics, or elements described in connection with other embodiments unless otherwise specifically indicated. Accordingly, various changes in form and details may be made without departing from the spirit and scope of the appended claims.

What is claimed is:

1. A display device comprising:
a display panel including a plurality of pixels which are configured to display an image,
wherein the display panel is divided into a plurality of areas including a first area and a second area, and
wherein a pixel disposed adjacent to a boundary between the first area and the second area includes a separation layer.

2. The display device of claim 1, wherein the separation layer extends parallel to the boundary, and is continuous.

3. The display device of claim 2, wherein the separation layer has a trapezoidal shape in a cross-sectional view.

4. The display device of claim 2, wherein the separation layer has an inverted trapezoidal shape in a cross-sectional view.

5. The display device of claim 2, wherein a first-first electrode included in a first pixel adjacent to the boundary in the first area and is electrically separated by the separation layer from a second-first electrode included in a second pixel adjacent to the boundary in the second area.

6. The display device of claim 5, wherein the first-first electrode and the second-first electrode are formed in a same layer, and
wherein voltages applied to the first-first electrode and the second-first electrode are different from each other.

7. The display device of claim 5, wherein the separation layer is formed on a pixel defining layer.

8. The display device of claim 1, wherein the separation layer includes one or more continuous sections parallel to the boundary and one or more discontinuous sections.

9. The display device of claim 8, wherein the continuous sections and the discontinuous sections are alternately disposed.

10. The display device of claim 8, wherein the separation layer has a trapezoidal shape in a cross-sectional view.

11. The display device of claim 8, wherein the separation layer has an inverted trapezoidal shape in a cross-sectional view.

12. The display device of claim 8, wherein, in the continuous section, a first-first electrode included in a first pixel adjacent to the boundary in the first area is electrically separated by the separation layer from a second-first electrode included in a second pixel adjacent to the boundary in the second area, and
wherein, in the discontinuous section, a third-first electrode included in a third pixel adjacent to the boundary in the first area is electrically connected to a fourth-first electrode included in a second pixel adjacent to the boundary in the second area.

13. The display device of claim 12, wherein the first-first electrode and the second-first electrode are formed in a same layer, and
wherein voltages applied to the first-first electrode and the second-first electrode are different from each other.

14. The display device of claim 12, wherein the separation layer is formed on a pixel defining layer.

15. An electronic device comprising:
a display panel including a plurality of pixels which are configured to display an image; and
an encapsulation layer disposed on the display panel,
wherein the display panel is divided into a plurality of areas including a first area and a second area, and
wherein a pixel disposed adjacent to a boundary between the first area and the second area includes a separation layer.

16. The electronic device of claim 15, further comprising:
a touch sensor disposed on the display panel; and
a window disposed on the touch sensor.

17. The electronic device of claim 15, further comprising:
a data driver electrically connected to the display panel;
a scan driver electrically connected to the display panel; and
an emission driver electrically connected to the display panel.

18. The electronic device of claim 15, wherein the electronic device is a tablet PC, a television, a smartphone, a notebook computer, a head mounted display, a display included in an automobile dashboard, a navigation system display, a digital camera, an electronic book, or a portable game console.
